(19) United States
(12) Patent Application Publication
(10) Pub. No.: US 2018/0295750 A1
(43) Pub. Date: Oct. 11, 2018

(54) Modular rack with adjustable size structures

(71) Applicant: Scalematrix, San Diego, CA (US)

(72) Inventors: Mark David Ortenzi, Escondido, CA (US); Chris Orlando, Escondido, CA (US)

(21) Appl. No.: 15/944,534

(22) Filed: Apr. 3, 2018

Related U.S. Application Data
(60) Provisional application No. 62/481,598, filed on Apr. 4, 2017.

(51) Int. Cl. H05K 7/20; H05K 7/14

(52) U.S. Cl. CPC H05K 7/20754; H05K 7/20736; H05K 7/1489

(57) ABSTRACT

An equipment rack, is formed with a bottom surface, a top surface, sidewalls extending between the top and bottom surfaces, and server racks extending along the sidewalls supporting computer components which are energized to create heat. The rear of the adjustable to accommodate different depth servers. The bottom of the equipment rack is extended up off the ground by at least 3 inches to allow for airflow under the rack. As the rear surface moves backwards and forwards to accommodate different width racks, the movement also allows more airflow behind the rack.

This application claims priority from provisional application No. 62/481,598, filed Apr. 4, 2017, the entire contents of which are herewith incorporated by reference.

### BACKGROUND

Computing equipment such as servers are often housed within a sealed or sealable housing rack. The rack can include structure to hold the different servers.

Different servers have different sizes.

### SUMMARY

The present application describes a modular rack that can be reconfigured between different sizes and has different structure allowing parts to be moved in and out of, and held into the rack.

### BRIEF DESCRIPTION OF THE DRAWINGS

Aspects of the drawings are described within with reference to the accompanying drawings

FIG. 1 illustrates a perspective view of the rack

FIG. 2 shows a side view of the rack from a different angle, illustrating the horizontal rails

FIG. 3 shows a bottom detail of the rack 300

FIG. 4 illustrates the front of the rack

FIG. 5 illustrates how the front of the ramp can be ramped

FIG. 6 shows the front view

FIG. 7 shows a top section of the rack; and

FIG. 8 shows the rack is closed at the top, and fitted with cooling equipment.

### DETAILED DESCRIPTION

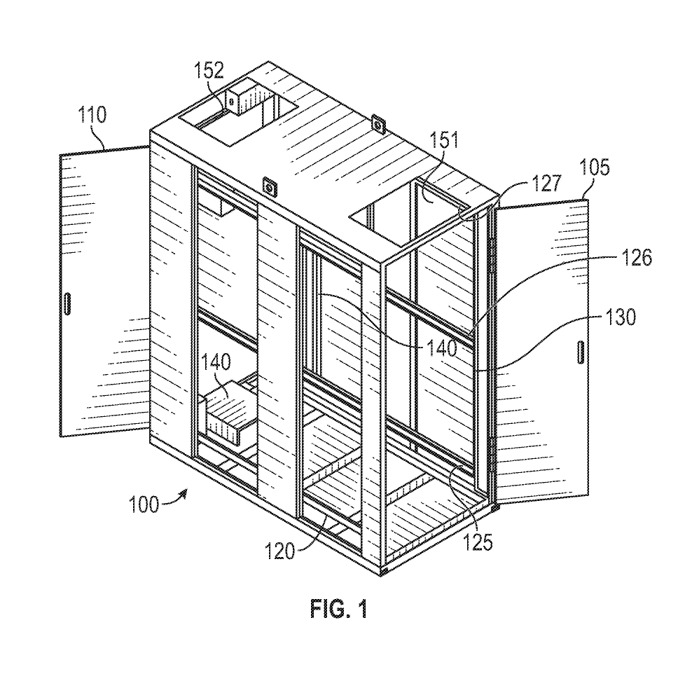

FIG. 1 illustrates a perspective view of the rack according to an embodiment. The rack 100 opens at its front with a front door 105 and at the rear via a rear door 110. Rack holding rails 120, 125 run inside the rack to hold the servers therein which will be held within the rack. The rack holding rails hold structure for holding the rack, along with vertical rails 130, hold structure for holding the servers inside the rack. The front vertical rail 130 (and a corresponding rail on the other side) is typically spaced 18 inches from the front of the rack in order to allow air flow through the front of the rack.

There are also open areas at the top of the rack 151, 152 through which power and cooling are provided as shown herein. In one embodiment, a cooling system can be located on the top of the rack.

As explained herein, there are also openings at the bottom of the rack to maintain airflow under the rack, and openings at the rear of the rack. To maintain airflow behind the rack.

The rear rail 140 according to the present application can be reconfigured depending on the depth of the servers that are placed into the racks.

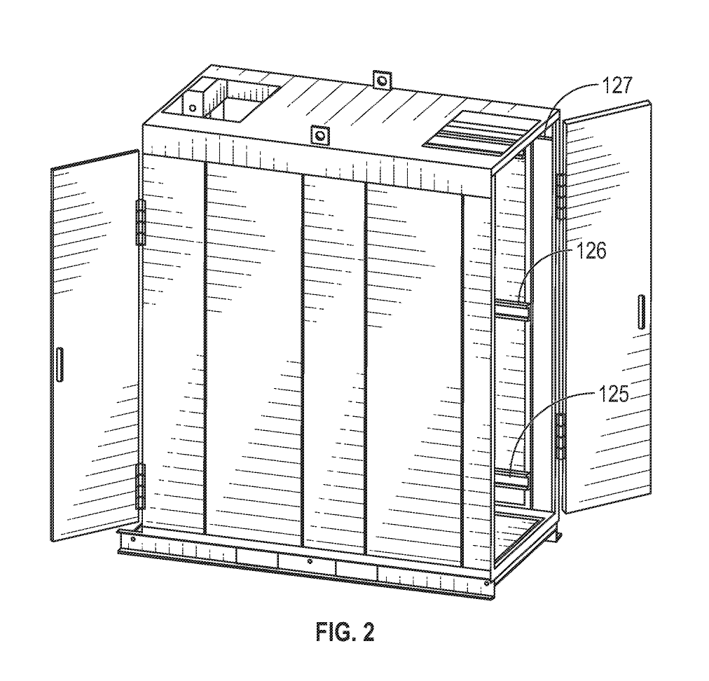

FIG. 2 shows a side view of the rack from a different angle, illustrating the horizontal rails 125,126, 127. While this shows only three horizontal rails, it should be understood that there can be many more rails to fit more shelves into the single rack.

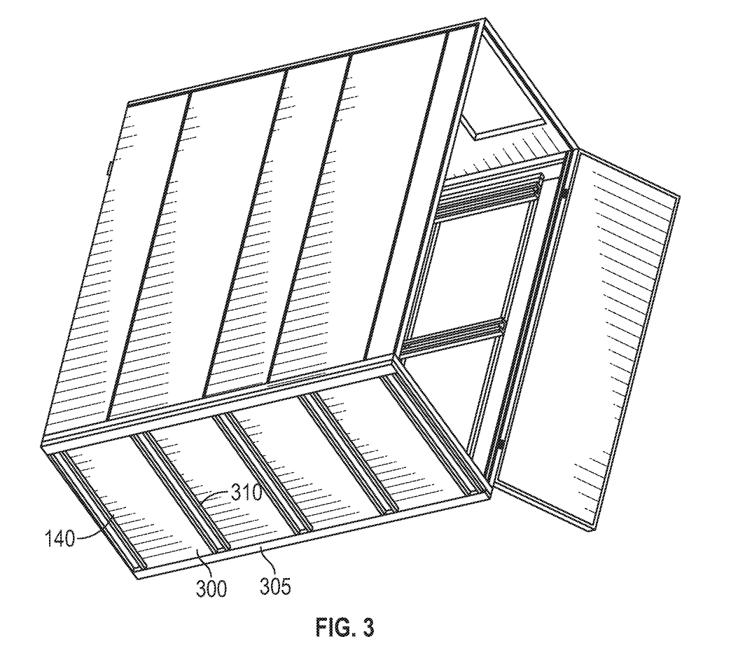

FIG. 3 shows a bottom detail of the rack 300 illustrating the structural supports 305 and crossbars 310. The location of the rear rail 140 is also shown.

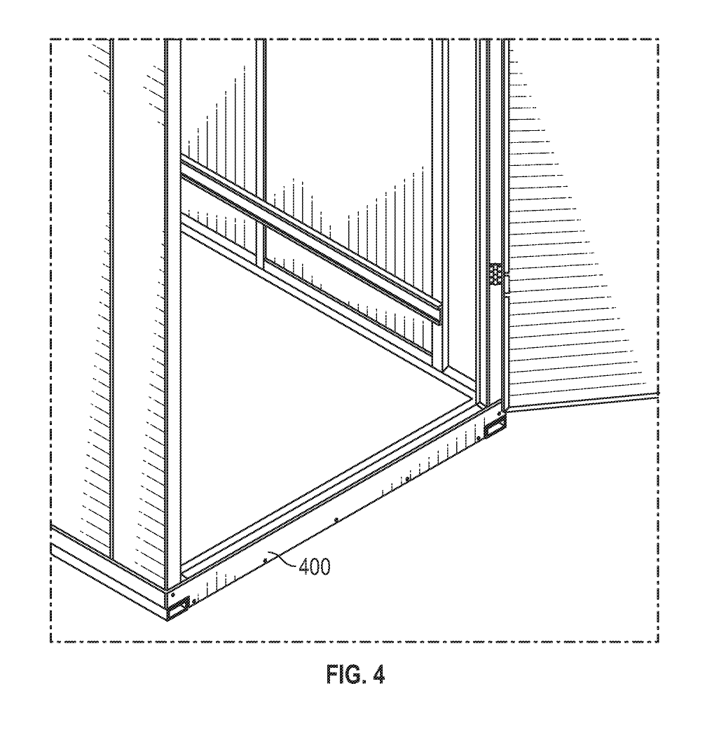

FIG. 4 illustrates the front of the rack, with a structural crossbar 400 spacing the bottom area of the rack from the floor. The structural crossbar causes this bottom area to be 3 to 4 inches off the ground to enable airflow under the rack.

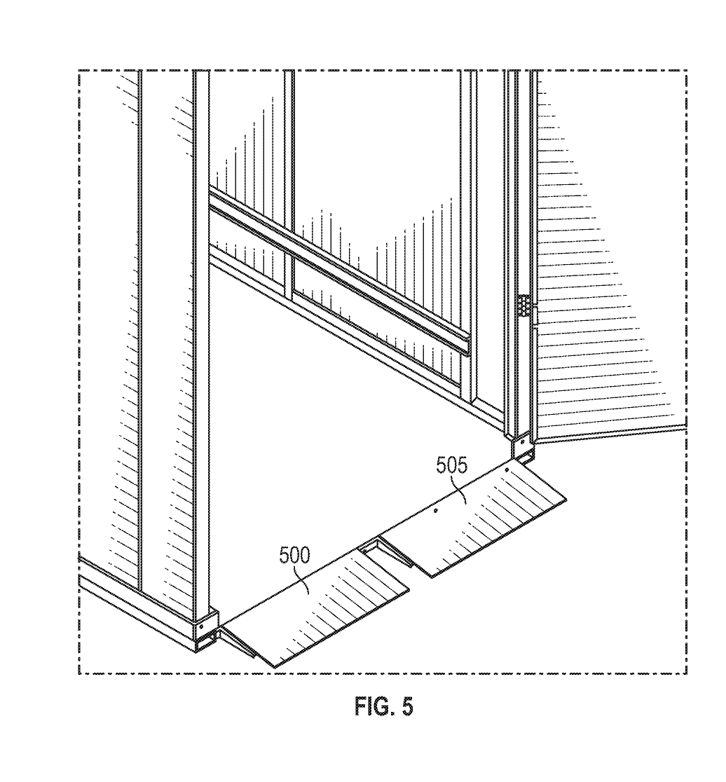

FIG. 5 illustrates how the front of the ramp can be ramped with ramps 500, 505 which ramp up enabling heavy loads to be wheeled into the cabinet.

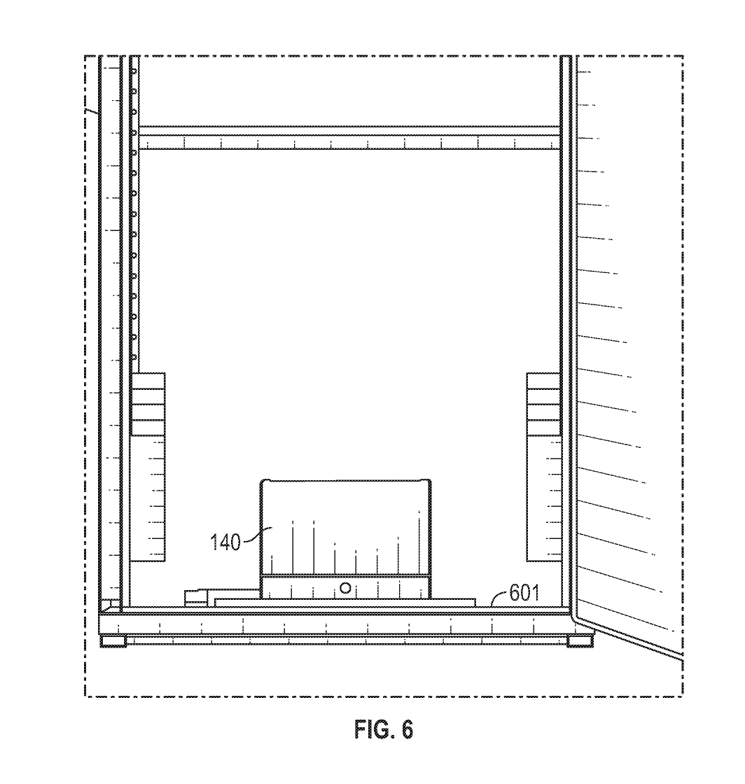

FIG. 6 shows a front view, illustrating the rear rail 140 at the rear of the cabinet. The rear rail has a bottom piece 601 whose top is located at the same level as the top surface of the bottom of the rack, e.g., 3 to 4 inches off the ground. The back facing piece of the rear rail extends upward from the bottom piece, and forms a back surface facing to the back of the servers that are in the rack. This surface can form a backstop to the racks, or can form a surface to provide, for example, power to the rack. Moreover, since this enforces the spacing under the rack, it facilitates cooling by providing an area under the rack for airflow, and the rear of this same rear rail maintains the airflow behind the servers mounted in the rack.

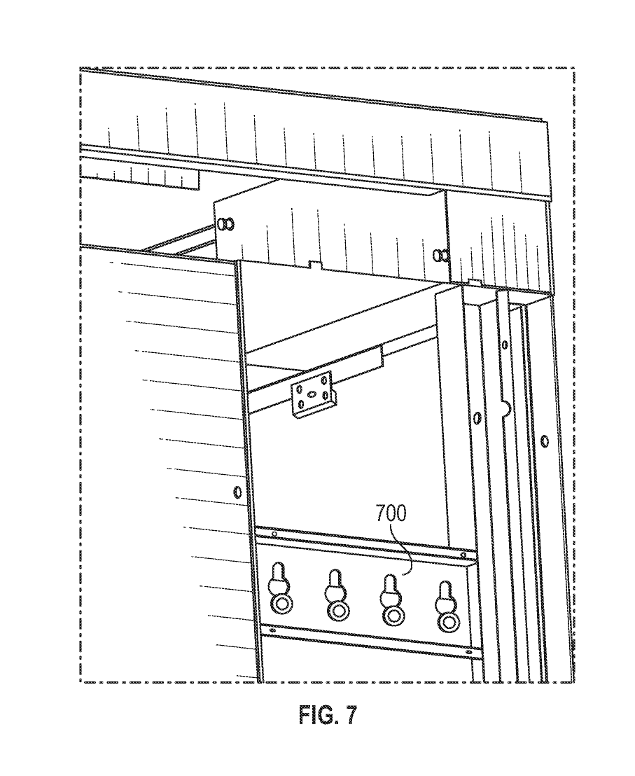

FIG. 7 shows a top section of the rack, illustrating the plate 700 which can be held on the rack in order to hold electrical connection parts.

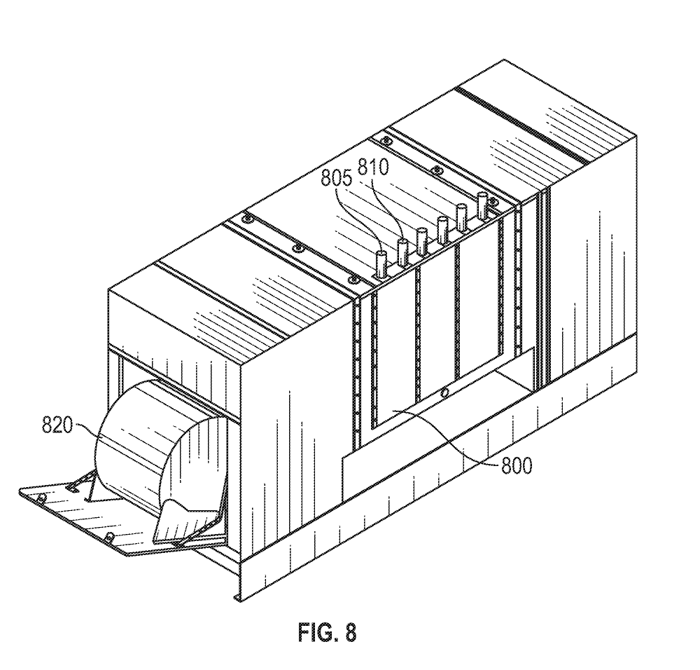

In operation, the rack is closed at the top, and fitted with cooling equipment 800 shown in FIG. 8. The cooling part includes coils that are provided with cooling fluid via the pipes 805 810 and others. The cooled coils cause cooling in the cabinet using the blower 820 which recirculates air in the cabinet over the cooled coils.

In operation, the vertical support 140 can be moved backward and forward depending on the desired length of the server. This can be used to accommodate different length servers, with smaller depth servers leaving more space behind the rack for airflow.

Although only a few embodiments have been disclosed in detail above, other embodiments are possible and the inventors intend these to be encompassed within this specification.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An equipment rack, comprising:
an equipment rack, having a bottom surface, a top surface, sidewalls extending between the top and bottom surfaces, and server racks extending along the sidewalls supporting computer components which are energized to create heat, between a front surface and a rear surface; and
a rear rail, which is moveable between positions, to change a distance between the front surface and the rear surface along which the server racks extend,
the bottom surface being defined by a bottom bar, which is at least 3 inches extended off the ground, and
the rear rail having a bottom surface which is also 3 inches off the ground, and also having a rear surface, perpendicular to the bottom surface, where the rear surface moves backwards and forwards to accommodate different width racks.

2. The equipment rack as in claim 1, further comprising ramps, which bridge between a level of the ground, and a level of the bottom surface of the rear rail having the equipment racks extending from front surface to a rear surface.

3. The equipment rack as in claim 1, where the bottom bar is a structural crossbar, spacing a bottom of the rack off the floor.

4. The equipment rack as in claim 3, further comprising cooling equipment, mounted on the rack, which circulates cooling air around the computer components.

5. The equipment rack as in claim 4, wherein the cooling equipment circulates the cooling air across a front of the computer components, a rear of the computer complements as defined by a location of the rear rail, and across a bottom of the equipment rack underneath the structural crossbar.

6. Equipment rack as in claim 5, further comprising doors on front and rear of the equipment rack, sealing the equipment rack into a closed loop.
